(19) United States
(12) Patent Application Publication
(10) Pub. No.: US 2016/0312361 A1
(43) Pub. Date: Oct. 27, 2016

(54) METHOD OF FORMING A FILM

(71) Applicant: Mitsubishi Electric Corporation, Tokyo (JP)

(72) Inventors: Makoto Takada, Fukuoka-shi (JP); Takashi Nagira, Tokyo (JP)

(21) Appl. No.: 15/202,624

(22) Filed: Jul. 6, 2016

Related U.S. Application Data
(63) Continuation of application No. 14/476,788, filed on Sep. 4, 2014.

(30) Foreign Application Priority Data
Dec. 17, 2013 (JP) 2013-260569

(51) Int. Cl. C23C 16/46

(52) U.S. Cl. CPC C23C 16/46

(57) ABSTRACT

A method of forming a film on a wafer by decomposing a material gas includes placing the wafer on a top surface of a susceptor, heating the susceptor, measuring the temperature of the top surface of the susceptor. supplying a flow of the material gas to a location above the top surface the susceptor, and thermally decomposing the material gas to deposit a film on the wafer. The quantity of the material gas supplied to the location above the top surface of the susceptor is adjusted and the density of the material gas at the location above the top surface of the susceptor is kept constant by controlling the flow of the material gas to the location above the top surface of the susceptor, including by increasing the flow of the material gas as the temperature of the top surface of the susceptor decreases.

### BACKGROUND OF THE INVENTION

1. Field of the Invention

The present invention relates to a film forming apparatus and method used for manufacturing a semiconductor device or the like.

2. Background Art

Japanese Patent Laid-Open No. 2004-165454 discloses a film forming apparatus for forming a film on a wafer (processing object) by introducing a material gas into a reaction furnace. This film forming apparatus is intended to measure a wafer temperature and reflect the measurement result in a film formation condition to obtain a desired film thickness.

When a film is formed on a wafer in a reaction furnace, a grown product is deposited also on a susceptor. A deposit deposited on the susceptor causes an amount of heat transmitting from the susceptor toward above the susceptor to decrease. This causes the temperature above the susceptor to decrease. For that reason, the density of the thermally decomposed material gas (hereinafter referred to as “decomposed gas”) decreases, resulting in a problem that quality of the growth film changes over the time.

### SUMMARY OF THE INVENTION

The present invention has been implemented to solve the above-described problem and it is an object of the present invention to provide a film forming apparatus capable of maintaining a density of a thermally decomposed material gas.

The features and advantages of the present invention may be summarized as follows.

According to one aspect of the present invention, a film forming apparatus includes a susceptor having a first portion that holds a wafer on a top surface thereof and a second portion connected to the first portion, a gas supply section that supplies a material gas to above the susceptor, a first heater that heats the first portion, a second heater that heats the second portion, and a temperature control apparatus that controls temperatures of the first heater and the second heater, wherein the temperature control apparatus keeps the temperature above the susceptor constant by increasing the temperature of the second heater while maintaining the temperature of the first heater during film formation onto the wafer.

According to another aspect of the present invention, a film forming apparatus includes a susceptor having a first portion that holds a wafer on a top surface thereof and a second portion connected to the first portion, a gas supply section that supplies a material gas to above the susceptor, a first heater that heats the first portion, a second heater that heats the second portion, a temperature control apparatus that controls temperatures of the first heater and the second heater, and a thermometer that measures a temperature of a top surface of the susceptor, wherein the temperature control apparatus keeps the temperature of the top surface of the susceptor constant by increasing the temperature of the second heater every time the measured temperature of the thermometer decreases while maintaining the temperature of the first heater during film formation onto the wafer.

According to another aspect of the present invention, a film forming apparatus includes a susceptor that holds a wafer on a top surface, a heater that heats the susceptor, a thermometer that measures a temperature of a top surface of the susceptor, a gas supply section that supplies a material gas to above the susceptor, a mass flow controller that adjusts the amount of gas supplied to the gas supply section, and a gas flow rate setting section that controls the mass flow controller, wherein the gas flow rate setting section keeps constant the density of the material gas thermally decomposed above the susceptor by controlling the mass flow controller so as to increase the amount of gas supplied to the gas supply section as the temperature of the thermometer decreases.

Other and further objects, features and advantages of the invention will appear more fully from the following description.

### BRIEF DESCRIPTION OF THE DRAWINGS

FIG. 1 is a cross-sectional view of a film forming apparatus according to a first embodiment;

FIG. 2 is a cross-sectional view of the film forming apparatus with a deposit deposited on the susceptor;

FIG. 3 shows temperatures of the first heater and the second heater;

FIG. 4 is a cross-sectional view of a film forming apparatus according to a second embodiment;

FIG. 5 is a diagram illustrating a temperature change of the thermometer and a temperature change of the second heater or the like; and

FIG. 6 is a cross-sectional view of a film forming apparatus according to a third embodiment.

### DETAILED DESCRIPTION OF THE PREFERRED EMBODIMENTS

A film forming apparatus according to an embodiment of the present invention will be described with reference to the accompanying drawings. The same or corresponding components will be assigned the same reference numerals and duplicate description may be omitted.

### First Embodiment

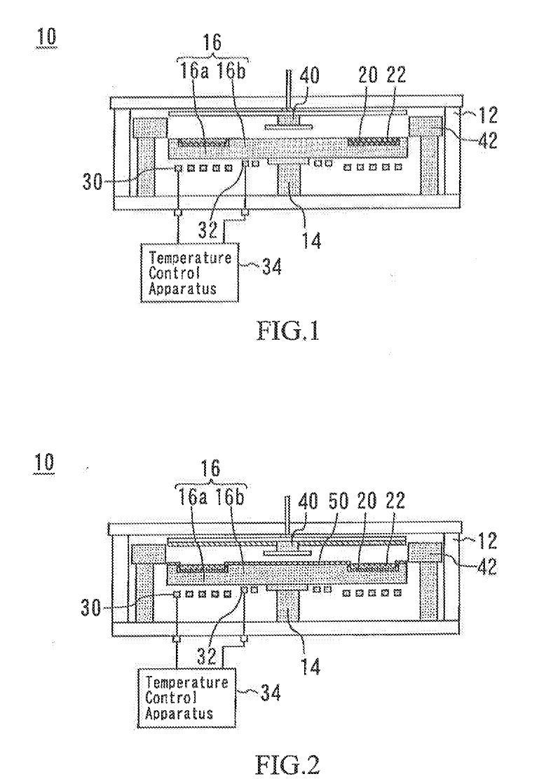

FIG. 1 is a cross-sectional view of a film forming apparatus 10 according to a first embodiment of the present invention. The film forming apparatus 10 is provided with a reaction furnace 12. An internal configuration of the reaction furnace 12 will be described. A susceptor 16 supported by a support stand 14 is provided in the reaction furnace 12. The susceptor 16 includes a first portion 16a that holds a wafer on a top surface thereof and a second portion 16b connected to the first portion 16a. The first portion 16a is a peripheral portion of the susceptor 16 and the second portion 16b is a central portion of the susceptor 16.

A dent is formed in the first portion 16a. A wafer 22 is mounted in this dent via a satellite disk 20. Therefore, the first portion 16a supports the wafer 22 via the satellite disk 20. Note that the satellite disk 20 is provided to achieve uniform film formation by rotating the satellite disk 20 itself, but may be omissible in the film forming apparatus of the present invention.

A first heater 30 to heat the first portion 16a is provided right below the first portion 16a. The first heater 30 is integrally formed, for example, in a concentric or spiral shape in a plan view. A second heater 32 to heat the second portion 16b is provided right below the second portion 16b. The second heater 32 is integrally formed, for example, in a concentric or spiral shape in a plan view.

A temperature control apparatus 34 is connected to the first heater 30 and the second heater 32. The temperature control apparatus 34 is intended to individually control temperatures of the first heater 30 and the second heater 32. The temperature control apparatus 34 may also be provided in the reaction furnace 12.

A gas supply section 40 is provided on a top surface of the reaction furnace 12. The gas supply section 40 is a section that supplies a material gas from outside the reaction furnace 12 to above the susceptor 16. The supplied material gas flows toward an peripheral direction of the susceptor 16 and is exhausted from an exhaust port 42.

A film formation method using the film forming apparatus 10 will be described. Here, as an example, a GaAsP film is formed using Ga which is a Group 3 element, and As and P which are Group 5 elements. While heating by the first heater 30 and the second heater 32 is in progress, the material gas of Ga, AsH₃ which is the material gas of As and PH₃ which is the material gas of P are supplied from the gas supply section 40 into the reaction furnace 12. These material gases are decomposed by heat from the susceptor 16 above the susceptor 16 and a decomposed gas allows GaAs(y)P(1−y) to epitaxially grow on the wafer 22. Here, y takes a value greater than 0 and smaller than 1.

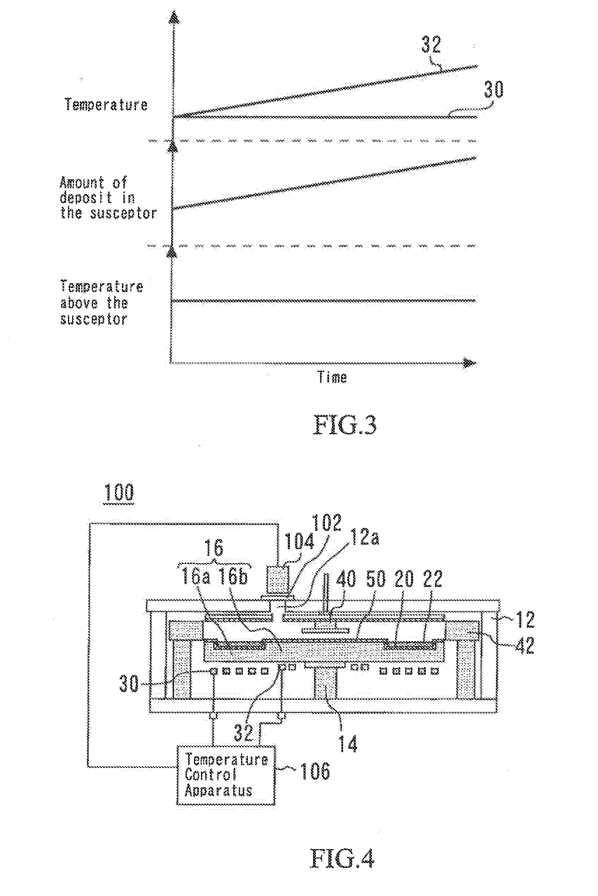

FIG. 2 is a cross-sectional view of the film forming apparatus 10 with a deposit 50 deposited on the susceptor 16. With the generation of the deposit 50, there is a concern about a decrease in the density of the decomposed gas. Therefore, in the first embodiment of the present invention, temperatures of the first heater 30 and the second heater 32 are controlled as shown in FIG. 3. That is, the temperature control apparatus 34 causes the temperature of the second heater 32 to increase while maintaining the temperature of the first heater 30 during film formation onto the wafer 22. The temperature increasing speed of the second heater 32 is determined in such a way as to be able to keep the temperature above the susceptor 16 constant. More specifically, influences of the deposit 50 on the temperature above the susceptor 16 is estimated from experiment data or a simulation or the like and the temperature increasing speed of the second heater 32 is thereby determined.

During film formation onto the wafer 22, the amount of deposit in the susceptor 16 increases, but it is possible to keep the temperature above the susceptor 16 constant by increasing the temperature of the second heater 32 while keeping the temperature of the first heater 30 constant. It is thereby possible to prevent changes over the times in the density of the decomposed gas and stabilize the quality of the growth film

Moreover, by maintaining the temperature of the first heater 30 which has great contribution to the temperature of the wafer 22, it is possible to keep the temperature of the wafer 22 substantially constant. By increasing the temperature of the second heater 32 which has small contribution to the temperature of the wafer 22, it is possible to increase the temperature of the second portion 16b while maintaining the temperature of the wafer 22.

As described above, the film formation method using the film forming apparatus 10 is intended to maintain the density of the decomposed gas on the premise of increasing deposits onto the susceptor 16, and it is therefore not necessary to replace the susceptor or remove the deposit deposited on the susceptor every time film formation processing is performed. It is thereby possible to solve the problems of a decrease of productivity and cost increase accompanying replacement of the susceptor or removal of the deposit.

The type of the material gas supplied into the reaction furnace 12 from the gas supply section 40 is not particularly limited if the material gas is thermally decomposed. The first heater 30 may be embedded in the first portion 16a and the second heater 32 may be embedded in the second portion 16b. Moreover, various modifications can be made within a range in which the features of the present invention will not be lost. These modifications are applicable to the film forming apparatus according to the following embodiments.

The film forming apparatuses according to the following embodiments will be described focusing on differences from the film forming apparatus 10 according to the first embodiment.

### Second Embodiment

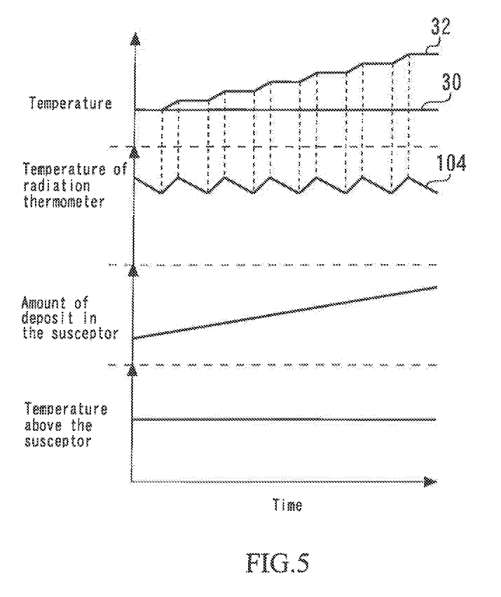

FIG. 4 is a cross-sectional view of a film forming apparatus 100 according to a second embodiment of the present invention. An opening 12a is provided on the top surface of the reaction furnace 12. The opening 12a is closed with a transparent material 102 such as glass which is transparent to light. A thermometer 104 is provided outside the reaction furnace 12 to measure a temperature of a top surface of the susceptor 16 via the transparent material 102. The thermometer 104 is a radiation thermometer that measures the temperature of the top surface of the second portion 16b.

The temperature control apparatus 106 is connected to the thermometer 104. The temperature control apparatus 106 causes the temperature of the second heater 32 to increase every time the measured temperature of the thermometer 104 decreases while keeping the temperature of the first heater 30 during film formation onto the wafer 22. FIG. 5 is a diagram illustrating a temperature change of the thermometer 104 and a temperature change of the second heater 32 or the like. As shown in FIG. 5, when the temperature of the thermometer 104 decreases as the amount of deposit on the susceptor increases, the temperature control apparatus 106 causes the temperature of the second heater 32 to increase. The temperature control apparatus 106 thereby keeps the temperature of the top surface of the susceptor 16 constant. This control is preferably performed automatically and in real time.

Since the present invention is intended to keep the temperature above the susceptor 16 constant, a place, a temperature of which is to be measured using the thermometer 104 is preferably a portion of the susceptor 16 that contributes most to the temperature above the susceptor 16. Since the portion of the film forming apparatus 100 that contributes most to the temperature above the susceptor 16 is the second portion 16b, the temperature of the second portion 16b was measured using the thermometer 104. However, if it is possible to keep the temperature above the susceptor 16 constant, the temperature of the first portion 16a may be measured.

### Third Embodiment

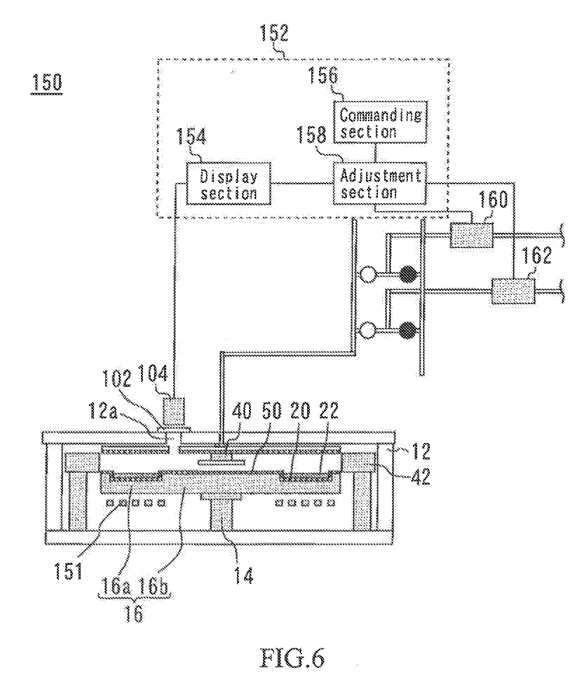

FIG. 6 is a cross-sectional view of a film forming apparatus 150 according to a third embodiment of the present invention. The film forming apparatuses according to the first and second embodiments are intended to keep the density of a decomposed gas constant by maintaining the temperature above the susceptor, whereas the film forming apparatus 150 is intended to keep the density constant by increasing the amount of gas supplied.

The film forming apparatus 150 is provided with the susceptor 16 that holds the wafer 22 on the top surface thereof. A heater 151 is provided right below the susceptor 16 to heat the susceptor 16. A gas flow rate setting section 152 is connected to the thermometer 104. The gas flow rate setting section 152 is connected to mass flow controllers 160 and 162 that adjust the amount of gas supplied to a gas supply section 40. The gas flow rate setting section 152 controls the mass flow controllers 160 and 162.

The gas flow rate setting section 152 is provided with a temperature display section 154 that displays a temperature measured using the thermometer 104. The gas flow rate setting section 152 is provided with a commanding section 156 that commands the amount of each material gas supplied so as to realize a preset film formation process. The temperature display section 154 and the commanding section 156 are connected to an adjustment section 158. The adjustment section 158 has data of a thermal decomposing rate of each material gas above the susceptor when the susceptor temperature is a reference temperature (predetermined temperature). The adjustment section 158 calculates a difference between this data and the thermal decomposing rate of each material gas above the susceptor at a temperature measured using the thermometer 104. Based on this difference in thermal decomposing rate, the adjustment section 158 outputs signals to the mass flow controllers 160 and 162 so that the density of the decomposed gas becomes a reference value (predetermined value).

Since the temperature of the thermometer 104 decreases as the amount of deposit onto the susceptor 16 increases, the gas flow rate setting section 152 controls the mass flow controllers 160 and 162 so as to increase the amount of gas supplied to the gas supply section 40 as the temperature of the thermometer 104 decreases. An increment in the amount of gas supplied is determined so as to be able to keep constant the density of the material gas thermally decomposed above the susceptor 16. Therefore, according to the film forming apparatus 150, even when deposit onto the susceptor 16 causes the temperature above the susceptor 16 to decrease, it is possible to maintain the density of the decomposed gas.

Another configuration may be adopted for the gas flow rate setting section 152 if it can increase the amount of the material gas supplied so as to maintain the density of the decomposed gas. The features of the film forming apparatuses of the respective embodiments described so far may be used in combination as appropriate.

According to the present invention, it is possible to maintain the temperature above the susceptor and increase the amount of the material gas supplied to thereby maintain the density of the thermally decomposed material gas.

Obviously many modifications and variations of the present invention are possible in the light of the above teachings. It is therefore to be understood that within the scope of the appended claims the invention may be practiced otherwise than as specifically described.

1-4. (canceled)

5. A method of forming a film comprising:
placing a wafer on a top surface of a susceptor;
heating the susceptor;
measuring the temperature of the top surface of the susceptor;
supplying a flow of a material gas to a location above the top surface the susceptor and thermally decomposing the material gas to deposit a film on the wafer;
adjusting quantity of the material gas supplied to the location above the top surface of the susceptor; and
keeping a constant density of the material gas at the location above the top surface of the susceptor by controlling the flow of the material gas to the location above the top surface of the susceptor, including increasing the flow of the material gas as the temperature of the top surface of the susceptor decreases.
